(19) United States
(12) Patent Application Publication
(10) Pub. No.: US 2013/0000965 A1
(43) Pub. Date: Jan. 3, 2013

(54) DIELECTRIC COMPOSITION, MULTILAYERED PRINTED CIRCUIT BOARD COMPRISING DIELECTRIC LAYER MANUFACTURED THEREOF, AND METHOD FOR PREPARING THE MULTILAYERED PRINTED CIRCUIT BOARD

(75) Inventors: Dong Joo SHIN, Gyeonggi-do (KR); Seong Min Chin, Gyeonggi-do (KR); Moon Soo Park, Gyeonggi-do (KR); Sung Taek Lim, Gyeonggi-do (KR); Sung Hyun Kim, Gyeonggi-do (KR); Choon Keun Lee, Gyeonggi-do (KR)

(73) Assignee: SAMSUNG ELECTRO-MECHANICS CO., LTD.

(21) Appl. No.: 13/469,614

(22) Filed: May 11, 2012

(30) Foreign Application Priority Data
Jun. 28, 2011 (KR) 10-2011-0062942

(51) Int. Cl. H05K 1/00; C08K 3/26; C08K 3/36; H01B 19/04

(52) U.S. Cl. 174/258; 216/16; 523/457

(57) ABSTRACT

Disclosed herein are a dielectric composition of a multilayered circuit board including two types of inorganic fillers of 10 to 60 parts by weight with respect to an epoxy resin of 100 parts by weight, a multilayered printed circuit board including a dielectric layer manufactured of the dielectric composition, and a method for preparing the multilayered printed circuit board.

According to the present invention, by mixing two types of inorganic fillers such as SiO₂ and CaCO₃ in manufacturing the dielectric layer of the multilayered circuit board, a high adhesive strength to a plating layer can be achieved without using a fluoride-based solution including 3NH₄HF₂ as an oxidant while etching the dielectric layer and furthermore, an environmentally hazardous substance can be prevented from being discharged.

### CROSS REFERENCE(S) TO RELATED APPLICATIONS

This application claims the benefit under 35 U.S.C. Section 119 of Korean Patent Application Serial No. 10-2011-0062942, entitled “Dielectric Composition Multilayered Printed Circuit Board Comprising Dielectric Layer Manufactured Thereof, And Method for Preparing the Multilayered Printed Circuit Board” filed on Jun. 28, 2011, which is hereby incorporated by reference in its entirety into this application.

### BACKGROUND OF THE INVENTION

1. Technical Field

The present invention relates to a dielectric composition for a dielectric layer of a multilayered printed circuit board, a multilayered circuit board comprising the dielectric layer manufactured thereof, and a method for preparing the multilayered circuit board.

2. Description of the Related Art

With the miniaturization and multi-function of digital electronic apparatuses, functions of advanced components have also been further upgraded. In particular, in the case of a multilayered PCB, a build-up dielectric film (dielectric layer) is used in order to implement and develop thin, highly integrated, and minute circuits for achieving high specifications.

The multilayered printed circuit board has a plurality of wiring patterns printed to have conductivity and the adjacent printed wiring patterns are electrically insulated from each other by the dielectric layer interposed therebetween.

The dielectric layer includes inorganic filler and the inorganic filler serves to increase a thermal characteristic of the dielectric layer and improve adhesive strength to a plating layer by removing filler exposed to the surface.

When the inorganic filler exposed to the surface of the dielectric layer is etched to be removed, roughness is formed on the surface of the dielectric layer in a space where the inorganic filler is positioned to improve the adhesive strength to the plating layer.

FIGS. 1 and 2 shown below are diagrams showing a process of forming roughness of the multilayered printed circuit board depending on whether or not to use a 3NH₄HF₂ solution. FIG. 1 is a case using the 3NH₄HF₂ solution and in a first step, a dielectric layer 20 including SiO₂ inorganic filler 11 is first formed on a copper substrate 10. In this case, the SiO₂ organic fillers 11 included in the dielectric layer 20 are exposed at the surface of the dielectric layer 20. Accordingly, the exposed inorganic fillers 11 are etched by using the 3NH₄HF₂. At this time, roughness A is formed on the surface of the dielectric layer by etching the inorganic filler 11 exposed at the surface of the dielectric layer 20. Therefore, a high peel strength is achieved due to an anchoring effect B during plating.

On the contrary, in the case of FIG. 2 in which the SiO₂ inorganic filler 11 exposed to the surface of the dielectric layer 20 is etched by using only a sulfuric acid (H₂SO₄) solution without using the 3NH₄HF₂ solution, the SiO₂ inorganic filler 11 is not etched, such that roughness cannot be formed on the surface of the dielectric layer 20. Therefore, a low peel strength with a plating layer is achieved to influence reliability of the multilayered printed circuit board.

As described above, in the etching step for forming roughness on the surface by removing the inorganic filler exposed to the surface of the dielectric layer, a fluoride-based solution including 3NH₄HF₂ is used sulfuric acid (H₂SO₄) is added thereto.

An etching reaction equation of the fluoride-based solution and the SiO₂ inorganic filler is shown below.

SiO₂+3NH₄HF₂→[NH₄]₂SiF₆+NH₄OH+H₂O (Reaction Equation 1)

However, the 3NH₄HF₂ solution is expensive and a waste liquid generated after using the 3NH₄HF₂ solution is an environmentally hazardous substance, which is significantly difficult to treat.

### SUMMARY OF THE INVENTION

Accordingly, in order to solve various environmental pollution caused due to the use of a fluoride acid solution or problem in adhesive strength to a plating layer in the related art, an object of the present invention is to provide a dielectric composition of a multilayered printed circuit board capable of increasing the adhesive strength to the plating layer without using an etching solution which is hazardous to an environment in the related art.

Another object of the present invention is to provide a multilayered printed circuit board including a dielectric layer manufactured by the dielectric composition.

Further, another object of the present invention is to provide a method for preparing the multilayered printed circuit board.

According to an exemplary embodiment of the present invention, there is provided a dielectric composition of a multilayered circuit board including two types of inorganic fillers of 10 to 60 parts by weight with respect to an epoxy resin of 100 parts by weight.

The two types of inorganic fillers may be SiO₂ and CaCO₃.

One type of inorganic filler of the two types of inorganic fillers may be included so as not to exceed 20 parts by weight in total inorganic fillers.

The inorganic filler may have D50 of 2 μm or less.

According to another exemplary embodiment of the present invention, there is provided a multilayered circuit board including a dielectric layer manufactured from a dielectric composition of the multilayered circuit board including two types of inorganic fillers of 10 to 60 parts by weight with respect to an epoxy resin of 100 parts by weight.

According to yet another exemplary embodiment of the present invention, there is provided a method for preparing a multilayered circuit board including: forming a dielectric layer on a printed circuit board; and etching the dielectric layer.

The dielectric layer may include two types of inorganic fillers of 10 to 60 parts by weight with respect to an epoxy resin of 100 parts by weight.

The etching of the dielectric layer may be performed without an additional oxidant.

The oxidant may be a fluoride-based solution including 3NH₄HF₂.

Inorganic filler exposed to the surface of inorganic fillers in the dielectric layer may be etched in the etching of the dielectric layer.

The inorganic filler may be CaCO₃.

An etching solution for etching the dielectric layer may be sulfuric acid (H₂SO₄).

Roughness may be formed by reacting the inorganic filler exposed to the surface and sulfuric acid (H₂SO₄) in the etching of the dielectric layer.

### BRIEF DESCRIPTION OF THE DRAWINGS

FIG. 1 is a diagram showing a process of forming roughness of a multilayered circuit board using a 3NH₄HF₂ solution in the related art.

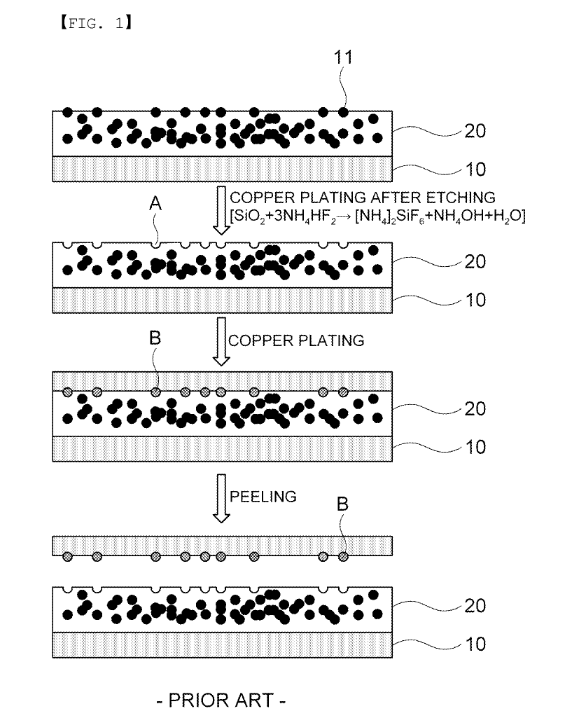

FIG. 2 is a diagram showing a process of forming roughness of a multilayered circuit board without using the 3NH₄HF₂ solution in the related art.

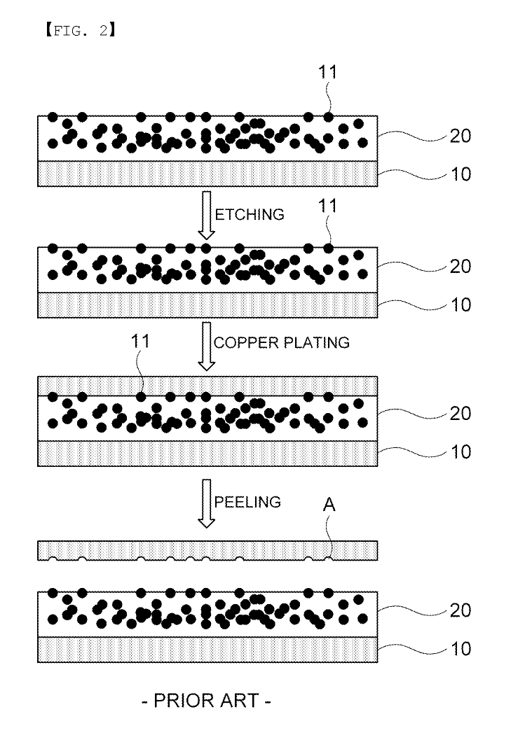

FIG. 3 is a diagram showing a process of forming roughness of a multilayered circuit board without using a 3NH₄HF₂ solution according to an exemplary embodiment of the present invention.

### DESCRIPTION OF THE PREFERRED EMBODIMENTS

Hereinafter, the present invention will be described in more detail.

Terms used in the specification are used to explain the embodiments and not to limit the present invention. In the specification, a singular type may also be used as a plural type unless stated specifically. “Comprises” and/or “comprising” used the specification mentioned constituent numbers, steps, operations and/or elements do not exclude the existence or addition of one or more other components, steps, operations and/or elements.

The present invention relates to a dielectric composition for a dielectric layer of a multilayered circuit board, a multilayered circuit board comprising the dielectric layer manufactured thereof, and a method for preparing the multilayered circuit board.

The dielectric composition includes two types of inorganic fillers of 10 to 60 parts by weight with respect to an epoxy resin of 100 parts by weight.

The epoxy resin includes a multi-functional epoxy resin made of glycidyl ether of a polyphenol compound, a multi-functional epoxy resin made of glycidyl ether of various novolak resins, an alicyclic epoxy resin, a heterocyclic epoxy resin, a glycidyl ester-based epoxy resin, a glycidyl amine-based epoxy resin, an epoxy resin glycidylating halogenated phenols, and the like, but is not limited thereto.

In the present invention, as inorganic filler, two types such as SiO₂ and CaCO₃ should be particularly mixed with each other. The inorganic filler includes 10 to 60 parts by weight and preferably 30 to 40 parts by weight with respect to the epoxy resin of 100 parts by weight.

When the content of the two types of inorganic fillers is less than parts by weight, a thermal expansion coefficient is remarkably deteriorated, such that a thermal characteristic is deteriorated and further, when the content is more than 60 parts by weight, the thermal characteristic is improved, but a dielectric characteristic is undesirably deteriorated. Further, appropriate roughness may be formed on the surface of the dielectric layer in an etching step in the range of the content.

According to the present invention, it is preferable that one type of inorganic filler between the two types of inorganic fillers is included so as not to exceed 20 parts by weight of total inorganic fillers because the inorganic filler may be used in a range in which the thermal expansion coefficient does not increase.

Further, in the case of the inorganic filler used in the present invention, D50 is preferably equal to or less than 2 μm and D50 is more than 2 μm, roughness of a dielectric material is increased, such that it is undesirably difficult to form minute pitch at the time of forming a circuit during a postprocess.

Further, various types of curing agents may be used for the dielectric composition according to the present invention in order to cure the epoxy resin. For example, various types of curing agents may include acid anhydride-based, amine-based, imidazole-based, hydrazine-based, Lewis acid, isocyanate-based, and the like, but are not particularly limited thereto.

Besides, it is apparent to those skilled in the art that various additives can be included with a small amount within the scope without influencing the formation of the dielectric layer of the present invention.

According to an exemplary embodiment of the present invention, there is provided a multilayered printed circuit board in which the dielectric composition is prepared and mixed to be appropriately dispersed in a liquid state, both sides of a top surface and a bottom surface of a copper substrate are coated with a mixture, and thereafter, a final dielectric layer is included by curing a coated layer. The thickness of the dielectric layer according to the present invention is preferably in the range of approximately 10 to 50 μm.

It is preferable that the dielectric composition is applied to the printed circuit board and cured at 120 to 210° C. for 20 to 60 minutes.

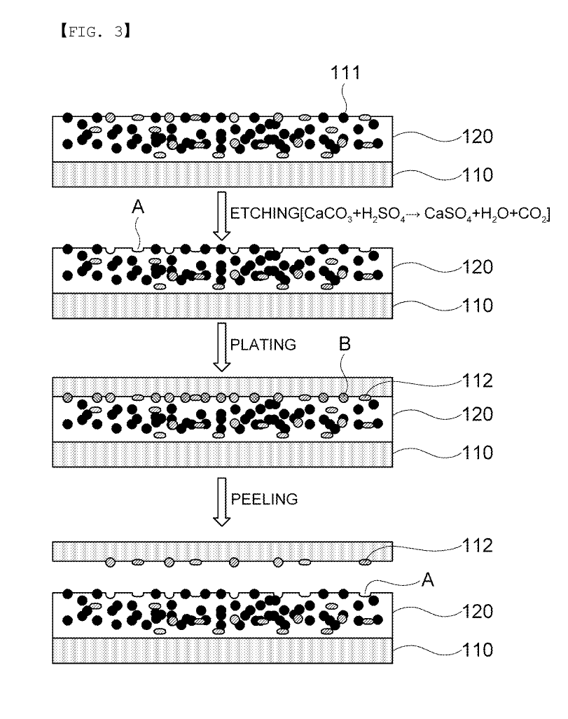

A method for preparing a multilayered printed circuit board according to the present invention will be described with reference to FIG. 3 described below. First, a dielectric layer 120 is formed on a printed circuit board 110. The dielectric layer 120 is preferably made of a composition including SiO₂ and CaCO₃, two types of inorganic fillers of 10 to 60 parts by weight with respect to an epoxy resin of 100 parts by weight. The thickness of the dielectric layer is preferably in the range of approximately 10 to 50 μm.

As shown in FIG. 3, SiO₂ 111 and CaCO₃ 112 which are the two types of inorganic fillers included in the dielectric layer 120 are uniformly dispersed in the dielectric layer 120. Further, the two types of inorganic fillers may be exposed at the surface of the dielectric layer 120.

Therefore, in a second step, a process of etching the dielectric layer is performed. The process is to form appropriate roughness on the surface of the dielectric layer 120 by etching the inorganic filler exposed at the surface of the dielectric layer 120.

In the present invention, the etching of the dielectric layer may be performed without using an additional fluoride-based oxidant which is environmentally problematic in the related art. That is, as the oxidant, a fluoride-based solution including 3NH₄HF₂ is excluded and etched by using only sulfuric acid.

When the sulfuric acid solution is used, SiO₂ between the inorganic fillers included in the dielectric layer remains as it is and only CaCO₃ is etched by reacting with sulfuric acid to form appropriate roughness A at a position thereof.

An etching reaction equation between the CaCO₃ inorganic filler and the sulfuric acid (H₂SO₄) solution is shown below.

CaCO₃+H₂SO₄—CaSO₄+H₂O+CO₂ (Reaction Equation 2)

Through the reaction, appropriate roughness is formed at a position where the CaCO₃ inorganic filler is present on the surface of the dielectric layer 120. Thereafter, when a plating layer 130 is formed on the dielectric layer 120, a high peel strength is achieved due to an anchoring effect B during plating.

Therefore, according to the present invention, in preparing the multilayered printed circuit board, CaCO₃ filler is mixed except for SiO₂ fillers, such that roughness which was not formed without using a 3NH₄HF₂ solution is etched by the sulfuric acid (H₂SO₄) solution to allow the anchoring effect with the plating layer. This is performed while a desmear process used in the related art is similarly used.

Hereinafter, an example of the present invention will be described in detail with reference to the accompanying drawings. However, the example is only to exemplify the present invention and it will not be appreciated that the scope of the present invention is limited by the example.

### Example 1

A composition for forming a dielectric layer was prepared by adding a curing agent, SiO₂ of 30 parts by weight and CaCO₃ of 8 parts by weight as inorganic fillers, and an accelerator, a leveling agent, and the like as other additives to an epoxy resin (bisphenol A type epoxy & novolac type epoxy) of 100 parts by weight.

The dielectric composition was applied to the printed circuit board and cured at 120 to 210° C. for 20 to 60 minutes to form a dielectric layer having a thickness in the range of 10 to 50 μm.

The inorganic filler exposed to the surface of the dielectric layer was added to a sulfuric acid solution to be etched. Thereafter, a plating layer was formed and peeled.

Next, as shown in FIG. 3, CaCO₃ which was the inorganic filler exposed to the surface of the dielectric layer was appropriately etched such that an anchor was formed on a finally prepared printed circuit board and it was verified that a peel strength was high.

As set forth above, according to the present invention, by mixing two types of inorganic fillers such as SiO₂ and CaCO₃ while manufacturing the dielectric layer of the multilayered circuit board, a high adhesive strength to a plating layer can be achieved without a fluoride-based solution including 3NH₄HF₂ as an oxidant during etching of the dielectric layer and furthermore, an environmentally hazardous substance can be prevented from being discharged.

While the present invention has been shown and described in connection with the exemplary embodiments, it will be apparent to those skilled in the art that modification and variation can be made without departing from the spirit and scope of the invention as defined by the appended claims.

What is claimed is:

1. A dielectric composition of a multilayered circuit board, comprising two types of inorganic fillers of 10 to 60 parts by weight with respect to an epoxy resin of 100 parts by weight.

2. The dielectric composition of a multilayered circuit board according to claim 1, wherein the two types of inorganic fillers are SiO₂ and CaCO₃.

3. The dielectric composition of a multilayered circuit board according to claim 2, wherein one type of inorganic filler of the two types of inorganic fillers is included so as not to exceed 20 parts by weight in total inorganic fillers.

4. The dielectric composition of a multilayered circuit board according to claim 2, wherein the inorganic filler has D50 of 2 μm or less.

5. A multilayered circuit board, comprising a dielectric layer manufactured from a dielectric composition of the multilayered circuit board including two types of inorganic fillers of 10 to 60 parts by weight with respect to an epoxy resin of 100 parts by weight.

6. A method for preparing a multilayered circuit board, comprising:
forming a dielectric layer on a printed circuit board; and
etching the dielectric layer.

7. The method for preparing a multilayered circuit board according to claim 6, wherein the dielectric layer includes two types of inorganic fillers of 10 to 60 parts by weight with respect to an epoxy resin of 100 parts by weight.

8. The method for preparing a multilayered circuit board according to claim 6, wherein the etching of the dielectric layer is performed without an additional oxidant.

9. The method for preparing a multilayered circuit board according to claim 8, wherein the oxidant is a fluoride-based solution including 3NH₄HF₂.

10. The method for preparing a multilayered circuit board according to claim 6, wherein inorganic filler exposed to the surface of inorganic fillers in the dielectric layer is etched in the etching of the dielectric layer.

11. The method for preparing a multilayered circuit board according to claim 10, wherein the inorganic filler is CaCO₃.

12. The method for preparing a multilayered circuit board according to claim 6, wherein an etching solution for etching the dielectric layer is sulfuric acid (H₂SO₄).

13. The method for preparing a multilayered circuit board according to claim 12, wherein roughness is formed by reacting the inorganic filler exposed to the surface and sulfuric acid (H₂SO₄) in the etching of the dielectric layer.
